(19) United States
(12) Patent Application Publication
(10) Pub. No.: US 2022/0407453 A1
(43) Pub. Date: Dec. 22, 2022

(54) LIGHTWEIGHT PASSIVE RADIATIVE COOLING TO ENHANCE CONCENTRATING PHOTOVOLTAICS

(71) Applicant: Purdue Research Foundation, West Lafayette, IN (US)

(72) Inventors: Peter Andrew Bermel, West Lafayette, IN (US); David Jonathan Kortge, West Lafayette, IN (US); Ze Wang, West Lafayette, IN (US); Zhiguang Zhou, San Jose, CA (US); Jie Zhu, West Lafayette, IN (US)

(21) Appl. No.: 17/585,470

(22) Filed: Jan. 26, 2022

Related U.S. Application Data
(60) Provisional application No. 63/143,059, filed on Jan. 29, 2021.

(51) Int. Cl. H02S 40/42; H01L 31/052; H02S 40/22

(52) U.S. Cl. CPC H02S 40/42; H01L 31/052; H02S 40/22

(57) ABSTRACT

A radiatively cooled solar array, including a downwardly-facing solar cell and a mirror positioned below the solar cell and oriented to direct sunlight onto the solar cell. The assembly also includes a heat sink in thermal communication with the solar cell and disposed opposite the mirror. The heat sink is in radiative communication through Earth's atmosphere with outer space.

### CROSS-REFERENCE TO RELATED APPLICATIONS

This patent application claims priority to co-pending U.S. provisional patent application Ser. No. 63/143,059, filed on Jan. 29, 2021.

### GOVERNMENT FUNDING

This invention was made with government support under DE-EE0004946, awarded by the Department of Energy; EEC1454315, EEC-1227110, and CBET-1855882, awarded by the National Science Foundation; and No0014-15-1-2833 and No0014-19-S-B001, awarded by the Office of Naval Research. The government has certain rights in the invention.

### BACKGROUND

Thermal management is extremely important for renewable energy systems such as photovoltaics (PV), thermophotovoltaics (TPV) and concentrating photovoltaics (CPV). Elevated operating temperatures not only reduce the efficiency of PV modules, but also substantially reduce their lifetimes. This is an even more acute issue for higher heat load systems, such as TPV and CPV, where low-bandgap PV cells are commonly used, making the system more sensitive to temperature increase. The encapsulated housing of CPV and TPV systems further suppresses convective cooling, leading to dramatic temperature rises.

Heat transfer methods potentially relevant to CPV and TPV systems are conduction, convection and radiation. Conventional PV cooling approaches usually only utilize convective or conductive heat transfer, such as heat sinks, convective or forced air cooling, liquid cooling, and the like. Some of these strategies require extra energy input and specially designed cooling systems, which can increase the cost, decrease system efficiency, and reduce overall system reliability. Radiative cooling, on the other hand, has been dismissed as being limited for most of the indoor and low-temperature applications, as the temperature difference between the object and ambient is not large enough to fully exploit its potential. Thus, there remains a need for more efficient heat reduction techniques that do not consume power. The present novel invention addresses these needs.

### SUMMARY

Radiative cooling can reject significantly more waste heat than convection and conduction at high temperatures by sending it directly into space. As a passive and compact cooling mechanism, radiative cooling is lightweight and does not consume energy. These qualities are promising for thermal management in outdoor systems generating low grade heat, such as concentrating photovoltaics (CPV) and thermophotovoltaics (TPV). Radiative cooling is effective over a wide range of working conditions, including heat loads from 6 to 100 W with different CPV cooling designs. A CPV system integrated with radiative coolers may achieve a 5 to 36° C. temperature drop and an 8% to 27% relative increase of open-circuit voltage for a GaSb solar cell, under a heat load of above 6 W. The temperature drops from radiative cooling may significantly improve CPV system lifetimes.

Radiative cooling can exceed convective cooling when:

σ(T4−Tr4)>h(T−Ta)\sigma(T\hat{ }4−T_a\hat{ }4)>h(T−T_a)

where σ\sigma is the Stefan-Boltzman constant, T is the system temperature, Tr T_r is the radiative cooling reservoir temperature, TaT_a is the convective coolant temperature, and h is the convective coefficient.

Radiative cooling can exceed conductive cooling when:

σ(T4−Tr4)>k∇T\sigma(T\hat{ }4−T_r\hat{ }4)>k\nabla T

where k is the conductive coefficient.

In one embodiment, a radiatively cooled solar array 10 include a downwardly-facing solar cell 15, a mirror 20 positioned below the solar cell 15 and oriented to direct sunlight onto the solar cell 15, and a heat sink 25 in thermal communication with the solar cell 15 and disposed opposite the mirror 20 (between the solar cell 15 and the sky). The heat sink 25 is thus in radiative communication through Earth's atmosphere with outer space.

The radiatively cooled solar array 10 further includes an optical concentrator 30 (such as a Fresnel lens) positioned between the mirror 20 and the solar cell 15 for focusing sunlight onto the solar cell 15. At least one glass or like composition (zinc sulfide, adhesive tape, or the like) radiative cooler 35 is operationally connected to the heat sink 25 for radiating heat away from the solar cell 15. The mirror 20 is adapted to track a solar source of sunlight and wherein the heat sink 25 radiates to an outer space location spaced from the solar source of sunlight, such as through an electronic controller 40 operationally connected to a solar sensor 45 and to a motor 50 that is likewise operationally connected to the solar array 10. A scaffold 55 may be operationally connected to the solar cell 15 and mirror 20, and a thermocouple or like temperature sensor 6o may be connected in thermal communication with the solar cell 15.

### BRIEF DESCRIPTION OF THE DRAWINGS

FIGS. 1A-C graphically illustrate the emissivities of two types of radiative cooler performance for thermal management; FIG. 1A shows ideal below-ambient cooler with unity emissivity in transparency window and zero elsewhere, suitable for buildings in order to achieve low steady-state temperature; FIG. 1B shows ideal above-ambient cooler with zero emissivity in solar spectrum and unity elsewhere, suitable for PV systems to produce high cooling power; and FIG. 1C shows a comparison of cooling power provided by radiative cooling and non-radiative cooling approaches. The ambient temperature, non-radiative cooling coefficient, and emissivity are assumed to be 28° C., 3 W/m²/K, and 0.83, respectively. The inset shows cooling power enhancement of thermal radiation growing very fast as temperature increases (to the fourth power of temperature for an ideal blackbody).

FIGS. 2A-2D schematically illustrate an example CPV assembly for the measurement of radiative cooling performance; FIG. 2A illustrates an exploded view of Chamber 1; FIG. 2B shows the electrodes and thermocouple connecting to the solar cell on the bottom of Chamber 1; FIG. 2C illustrates tracing solar rays into the chambers; and FIG. 2D shows the entire CPV assembly.

FIGS. 3A-3C illustrate the assembly of FIGS. 2-2D during an outdoor test, with FIG. 3A showing the experimental environment; FIG. 3B showing the focused beam spot falling on the center of the solar cell; and FIG. 3C showing the reflection of the three chambers through the Al mirrors.

FIG. 4A-4D graphically illustrate experimental (solid lines) and simulation (shaded areas/dashed line) data for daytime radiative cooling; FIG. 4A illustrates temperature as a function of time; FIG. 4B illustrates voltage as a function of time; FIG. 4C shows temperature as a function of time with convective cooling as well as radiative cooling; and FIG. 4D shows voltage as a function of time with convective cooling as well as radiative cooling.

FIG. 5A-5C graphically illustrate simulations of various CPV cooling designs under a wide range of working conditions at 28° C. ambient; FIG. 5A shows temperature drop as a function of heat load; FIG. 5B shows lifetime improvement factor as a function of het load; and FIG. 5C shows temperature drop as a function of heat load.

FIG. 6A graphically illustrates reflectance/transmittance as a function of wavelength.

FIG. 6B graphically illustrates emissivity/transmittance as a function of wavelength.

FIG. 7 schematically illustrates cooling chamber geometry.

### DETAILED DESCRIPTION

For the purposes of promoting an understanding of the principles of the invention and presenting its currently understood best mode of operation, reference will now be made to the embodiments illustrated in the drawings and specific language will be used to describe the same. It will nevertheless be understood that no limitation of the scope of the invention is thereby intended, with such alterations and further modifications in the illustrated device and such further applications of the principles of the invention as illustrated therein being contemplated as would normally occur to one skilled in the art to which the invention relates.

For outdoor applications, radiative cooling is a powerful tool for thermal management for buildings and PV systems as a result of direct access to the Earth's atmosphere transparency window from 8 to 13 μm. Photons with wavelengths in this range can go through the atmosphere and exchange heat directly with outer space at a temperature around 3 Kelvin. This large temperature difference enables outdoor radiative coolers to efficiently remove a great deal of waste heat. It should be noted that above-ambient cooling does not require outdoors operation.

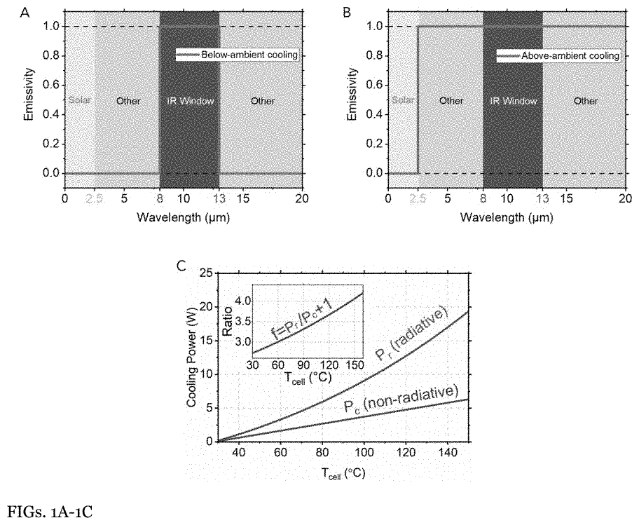

Radiative cooling can be classified as either below-ambient cooling or above-ambient cooling, as shown in FIGS. 1A and 1B. Below-ambient cooling aims for low steady-state temperatures, ideally to use in a cooler with unity emissivity in the transparency window and zero elsewhere. However, the cooling power is limited due to the narrow radiation spectrum range. Above-ambient cooling, on the other hand, aims to provide a maximum cooling power, which ideally requires the cooler to absorb no power within the solar spectrum, and emit as a blackbody at longer wavelengths.

A wide range of materials and structures have been demonstrated to provide radiative cooling. For example, nighttime below-ambient cooling does not require suppression of emission within the solar wavelengths. Bulk and composite materials with strong emissivity in the transparency window are also useful in the radiative transmission of waste heat. Daytime below-ambient cooling was not achieved until very recently, due to the challenges of simultaneously producing both strong IR emittance and low solar absorption. The emergence of nanophotonic and metamaterial coolers has now made it possible to tailor the emittance spectrum more precisely than has been achieved with traditional bulk materials. Much stronger and flatter emittance plateaus in the atmospheric transmission window have now been achieved while suppressing solar absorption, enabling net cooling even under direct sunlight. Meanwhile, above-ambient cooling with broadband IR emittance has also been proposed and studied recently, which can provide a great deal of cooling for objects at high temperatures. Moreover, given a proper design, broadband coolers may also be used for below-ambient cooling, since the thermal heat exchange with the sky outside of the transparency window can provide additional cooling power at near-ambient temperature.

Different types of radiative cooling may be elected, depending on the working temperature of a given system. For example, below-ambient cooling is widely used for thermal management of buildings, while above-ambient radiative cooling is more suitable for dissipating low grade heat from PV systems, as the elevated working temperature and high sky transmittance creates ideal conditions for maximizing the cooling power. Unlike forced air or liquid cooling for PV systems, which can consume from 2% to 5% of total output power, radiative cooling is passive with no extra energy consumption. It is also compact, lightweight, and reliable, without the bulky heat sinks or moving parts as are required for air and/or liquid cooling. This aspect may be especially beneficial with PV or CPV modules integrated with tracking systems. More importantly, the radiative power is significantly larger and grows quickly at high temperatures. The rate of heat dissipation is proportional to the fourth power of the temperature difference between the two objects, and scales much faster than conduction and convection. The efficient, compact, and passive nature of radiative cooling makes it an outstanding cooling mechanism for PV systems.

Recent research has shown the effects of radiative cooling in PV, TPV and CPV systems. For example, a GaSb based CPV system with a soda-lime radiative cooler has been experimentally demonstrated. A 10° C. drop of the solar cell was achieved under 13 suns, leading to a relative increase of 5.7% in open-circuit voltage and an estimated 40% increase in lifetime.

The instant novel technology relates to the radiative cooling performance of CPV in three different cooling structures, under a range of wind speeds and solar heat loads. Multiple outdoor experiments were conducted covering the worst and best possible working scenarios for radiative cooling to check the overall performance. The experiments show that radiative cooling, depending on the working conditions, can contribute roughly 25 to 62% of the overall cooling power of a CPV system equipped with flat-plate heat sink, while adding little weight and no extra power consumption. A high-concentration PV system integrated with radiative cooling was designed, refined, and fabricated. The average heat load on the solar cell was ˜5 to 6 W. By applying two soda-lime radiative coolers positioned on either side of the heat sink, the temperature drop of GaSb cell at steady-state for worst/best cases are 5° C. and 36° C., respectively. The maximum temperature drop even outperforms some active air-cooling methods. The temperature decrease also results in an 8% to 27% (28 to 75 mV) relative (absolute) increase in the open-circuit voltage of our GaSb PV cell, as well as a projected lifetime extension for various types of solar cells which potentially can be used in CPV systems. Using detailed simulations, a peak radiative power flux of 157 to 310 W/m² was estimated to be present, thereby increasing the cooling performance per unit weight by 25% to 81%. This improvement is particularly beneficial to PV systems with solar trackers. To better illustrate the concept, the specific cooling power Sₚ is given as:

$${S}_{p} = \frac{{P}_{r} + {P}_{c}}{m ( {T}_{cell} - {T}_{a} )} \qquad ( 1 )$$

where Pᵣ and P_{c} are the radiative and non-radiative cooling power, respectively; m is the total weight of the entire cooling assembly; T_{cell} is the solar cell temperature; and Tₐ is the ambient temperature.

For cooling systems working at the same temperature, a higher Sₚ indicates a greater cooling power per unit weight. By integrating radiative cooling into the CPV, the Sₚ increase can be calculated as a ratio factor f, which is given by

$$f = \frac{{S}_{p , r}}{{S}_{p , c}} \approx \frac{( {P}_{r} + {P}_{c} )}{{P}_{c}} = \frac{σε ( {T}_{cell}^{4} - {T}_{a}^{4} )}{{h}_{eff} ( {T}_{cell} - {T}_{a} )} + 1 \qquad ( 2 )$$

where S_{p,r} and S_{p,c} are the specific cooling power of an assembly with and without radiative cooling, respectively; h_{eff} is the effective coefficient for non-radiative heat transfer; σ is the Stefan-Boltzmann constant; and ε is emissivity of the cooler. The approximation is valid as long as the coolers are much lighter than the remainder of the cooling assembly, and the operating temperatures remain the same. It is straightforward to show that f˜T_{cell}³ when T_{cell} is large, which implies that radiative cooling is more resilient to high temperature systems than other cooling methods. FIG. 1C gives a better interpretation of the specific cooling power improvement. As temperature increases, the radiative cooling power grows to quickly dominate the total cooling power, providing a substantially larger Sₚ. The total cooling power must match the heating power reaching the PV system under thermal steady-state. Thus, with radiative cooling, PV can work under higher solar concentrations at the same temperature, to improve efficiencies and power outputs.

### EXAMPLE

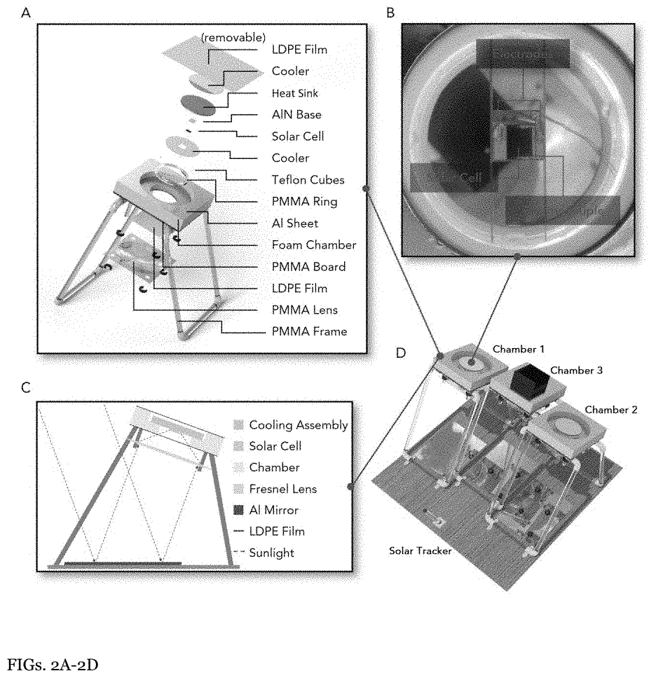

A radiative cooling measurement platform was built having three chambers, as illustrated in FIG. 2B. Each chamber performs different functions. Chamber 1, as shown in FIG. 2A, contains a solar cell and two soda-lime glass radiative coolers, while Chamber 2 has a similar solar cell structure without any coolers. Instead, aluminum (Al) reflectors are used in Chamber 2 as a control to minimize the solar heating and suppress the temperature, which is commonly used as heat sink or solar reflector for cooling outdoor devices under direct sunlight. The top LDPE films in both chambers may be attached or removed to represent different working conditions. The sealed-chamber structure (with top LDPE) can serve as a reference for two different scenarios. First, it roughly represents the zero-wind-speed working condition of CPV (natural convection), since the LDPE film can cut off direct convection from the heat sink to ambient air. Second, the sealed chamber configuration can be compared with active air-cooled CPV at zero air-injection rate; since many actively-cooled CPV systems require an enclosed fluid channel. In either case, the sealed-chamber structure gives the highest possible temperature drop from radiative cooling.

On the other hand, the open-chamber structure (without top LDPE) is best compared to passively air-cooled CPV, which is commonly found in commercial CPV. Both structures were tested outdoors and showed considerable temperature drops. Electrode probes and type-K thermocouples were mounted to the solar cells in Chambers 1 and 2 to measure their open-circuit voltages (V_{OC}) and temperatures (Tₑₓₚₜ), as shown in FIG. 2B. Chamber 3 only had a thermal power sensor to monitor the incident solar power. All three chambers were equipped with a Fresnel lens with effective diameter of 6 inches. Considering the zenith angle of sunlight at the field test location, all chambers were tilted at 20° and fixed on a wood board to maintain the same orientation, which orients the top cooler horizontally during experiments to maximize its view factor to the sky. The wood board was held by a tripod, the tilt and azimuth angles were adjusted to track the sun. Three first-surface Al mirrors were placed on the board under each chamber separately to reflect sunlight normally to the acrylic (PMMA) Fresnel lens, as shown in FIGS. 2B and 2D. A PMMA rod was fixed in front and tilted 20° to serve as a solar tracker.

### Daytime Radiative Cooling Field Test

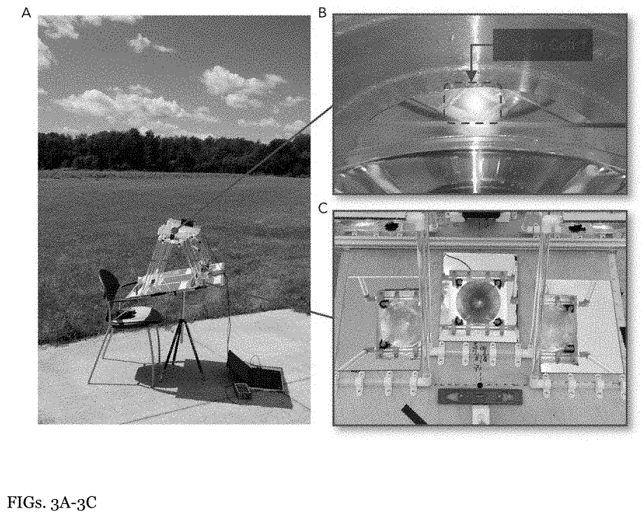

A daytime outdoor cooling experiment was conducted as shown in FIG. 3. LDPE covered both chambers during the experiment. The site had open access to the sky to guarantee the expected cooling performance, as shown in FIG. 3A. The role that each of the three chambers played in the experiment is described above. Before the test, all three chambers were aligned to the same level and warmed up by exposure to direct sunlight for 30 minutes, to reach a steady-state temperature close to ambient. During the test, the tilt and azimuth angles of the assembly were iteratively adjusted at 5-minute intervals to focus the beam spot on the center of the solar cells, as shown in FIGS. 3B and 3C. The temperature Tₑₓₚₜ and open circuit voltage V_{OC} of solar cells for both Chamber 1 and Chamber 2 were measured at resolutions of 0.096° C. and 0.12 mV, respectively, with a 2 Hz sampling rate. The thermal power meter in Chamber 3 monitored the input solar irradiance at a rate of 1 Hz. A laboratory chair and a tripod were used to stabilize the test assembly against vibrations caused by the wind. The experiment lasted for 1.5 hours to ensure that both chambers reach an instantaneous thermal steady-state.

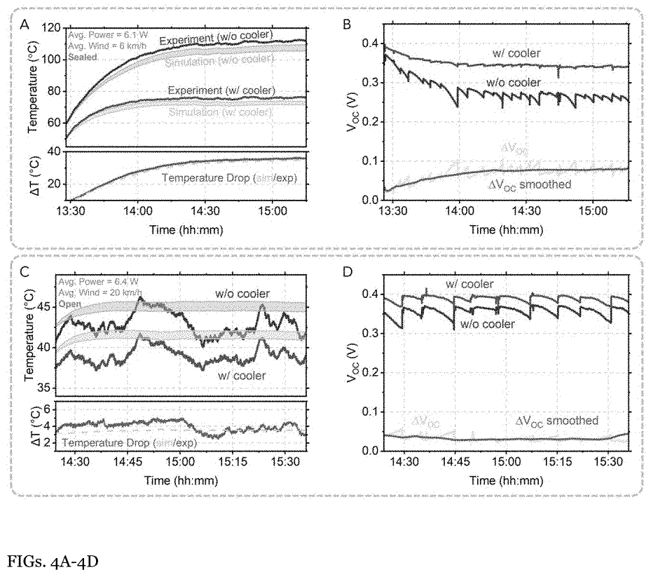

The measured real-time solar cell temperatures Tₑₓₚₜ, as well as a simulation of this experiment are shown in FIG. 4A. The shaded areas of the simulated temperatures account for the errors caused by uncertainties in the solar power meter measurements in Chamber 3. The experimental data and simulation results exhibit a very good match to the level of uncertainty, suggesting that the model may reflect the most important physical effects on the instantaneous thermal steady-state of the system. The real-time V_{OC} values for the solar cells in the two chambers are shown in FIG. 4B. With the Fresnel lens, the average focused solar irradiance during experiment was measured to be around 6.1 W, corresponding to a direct normal irradiance (DNI) of 1019 W/m². It can be seen in the figures that the differences between chambers of both Tₑₓₚₜ and V_{OC} values are smallest at the beginning of the experiment, since both chambers start at similar, above-ambient temperatures caused by solar heating during the 30-minute warmup phase. Upon direct solar heating, temperatures rise significantly in both chambers, thus reducing V_{OC} for both cells at different rates. More specifically, the temperature of Chamber 1 (with coolers) increases more slowly than the temperature of Chamber 2 (without coolers), as expected. Given that the structures and environments of the two chambers are nearly identical, except for the presence of the radiative coolers, the temperature differences observed are attributed to the additional cooling power of the radiative coolers. The V_{OC} of Chamber 1 also drops more slowly than that of Chamber 2, which implies higher electric power generation. The zigzag curves of the V_{OC} are caused by manual solar tracking, where each small jump corresponds to regular micro-adjustments of the tilt and azimuth angles with respect to the sun. This behavior is not observed in FIG. 4A, because the heat capacity of the system is relatively significant. This causes the temperature of the cooling assembly to respond to the beam spot shifts with a time constant on the order of one minute. It can also be noticed that the V_{OC} increases in Chamber 1 at each jump, but decreases in Chamber 2. This divergence in behavior is likely caused by the different local absorptance of the two cells, as well as the slightly different patterns of focused beam spots. This means the reduced energies on both solar cells are not identical, even if the shifted distances of the spots are the same during each adjustment. Both chambers reached instantaneous thermal steady-state at roughly 14:30. The temperature drop caused by the coolers is 36° C. at their peak values, which even outperforms some active air cooling while requiring no energy consumption. This significant temperature decrease led to a higher open-circuit voltage around 75 mV, corresponding to a 27% relative increase (since the shifts of V_{OC} are different in the two chambers, only the highest 10% of V_{OC} readings from each chamber are considered to provide a fair comparison, for when the beam spots are well focused on both).

To investigate radiative cooling in the more challenging case of high convection, a similar daytime outdoor cooling experiment without a top LDPE film installed was conducted on a windy day (wind speed 20 km/h). The results can be seen in FIGS. 4C and D. As expected, temperatures in both chambers are lower than the sealed-chamber case because of increased convection. Fluctuations in FIG. 4C are greater than in FIG. 4A, as the heat sink is now much more sensitive to wind gusts. While hourly wind speed data used in simulations misses fluctuations from wind gusts, the average temperature matches experiments closely. The measured temperature drop in Chamber 1 is ˜3 to 5° C. under an average wind speed of 20 km/h (previously, it was only 6 km/h). Simulations show that wind speed increases raise the effective convective heat transfer coefficient of the heat sink inside chamber from ˜3 W/m²/K to 20 W/m²/K. Although the temperature drop is not as high as the sealed-chamber case, the open-circuit voltage in Chamber 1 (with cooler) is still ˜28 mV greater than Chamber 2 (without cooler), as shown in FIG. 4D, corresponding to an 8% relative increase.

More experiments were conducted on different days to cover a wider range of heat loads and convective heat transfer coefficients. The heat transfer uniformity of Chamber 1 and 2, as well as the electrical characteristics of GaSb solar cells in both chambers have also been tested in separate experiments and show a very close performance.

### Quantitative Simulation Analysis

The experiments described above were also simulated. Results are shown in Table 1.

TABLE 1
Key Simulation Results for Outdoor Field Test

| | | Sealed-Chamber | | Open-Chamber | |
|---|---|---|---|---|---|
| Steady-State | | Cham- | Cham- | Cham- | Cham- |
| Solution | Notation | ber 1 | ber 2 | ber 1 | ber 2 |
| Solar Cell | T_{cell}[° C.] | 73.9 | 110.5 | 38.8 | 42.7 |
| Temperature | | | | | |
| Cooling Power per | P_{r, up}/ | 309.5 | 37.8 | 157.2 | 10.9 |
| Unit Area (up) | P_{cooler, up} | | | | |
| | [W/m²] | | | | |
| Cooling Power per | P_{r, down}/ | 169.6 | 28.0 | 45.1 | 4.9 |
| Unit Area (down) | P_{cooler, down} | | | | |
| | [W/m²] | | | | |
| Total Radiative | Pᵣ [W] | 3.6 | 0.5 | 1.6 | 0.13 |
| Cooling Power | | | | | |
| Total Input Power | Pᵢₙ [W] | 5.9 | 5.8 | 6.4 | 6.3 |
| Direct | hₐᵢᵣ | — | — | 28.5 | 28.5 |
| Convective | [W/m²/K] | | | | |
| Coefficient | | | | | |
| Effective | h_{eff} | 2.8 | 3.7 | 19.1 | 19.3 |
| Convective | [W/m²/K] | | | | |
| Coefficient | | | | | |
| Specific Cooling | Sₚ | 0.49 | 0.27 | 1.62 | 1.30 |
| Power | [W/kg/K] | | | | |

For the sealed-chamber case, the net cooling power of the top soda-lime glass cooler and the Al reflector are found to be ˜310 W/m² and ˜38 W/m², respectively. The power provided by the cooler is almost one order of magnitude greater than that given by the Al reflector. Although the bottom cooler and the Al reflector do not face the sky, the cooling power from cooler is still significantly higher than that provided by the Al reflector. Thus, both the top and bottom coolers contribute a large amount of cooling power, providing ˜62% of the total. This also illustrates that radiative cooling can still provide considerable cooling power for above-ambient applications, even without direct sky access. The effective convective coefficient h_{eff} for the assembly disk (including top, bottom, and side surface areas) is 2.8 W/m²/K in Chamber 1 and 3.7 W/m²/K in Chamber 2. The higher convective coefficient in Chamber 2 is likely caused by higher buoyancy-driven convection, induced by higher operating temperatures. Moreover, due to the compactness and high cooling flux of radiative cooling, the specific cooling power Sₚ of the assembly disk is greatly improved, as illustrated in Equation 1. In the test assembly, the Sₚ in Chamber 1 is 0.49 W/kg/K, as a result of both radiative and convective cooling; while in Chamber 2, the Sₚ is only 0.27 W/kg/K without radiative cooling. Simply by applying two layers of soda-lime glass wafers, the Sₚ can increase by 81% without any extra energy input in a sealed-chamber structure. For the open-chamber case, despite a lower temperature drop, the radiative cooling power from coolers still greatly exceeds that of Al reflectors, contributing ˜25% of the total cooling power, with net values of 157.2 W/m² and 10.9 W/m² from the top surfaces, respectively. Direct access to ambient air increases the effective convective coefficients l_{eff} of the cooling assembly disks to 19.1 and 19.3 W/m²/K, respectively, whereas the convective coefficient hₐᵢᵣ of the top surface in direct contact with ambient air is 28.5 W/m²/K for both chambers. As a reference, for outdoor experiments with the open chamber, the typical value of h_{eff} is approximately 10 W/m²/K. The unusually high h_{eff} causes a lower temperature drop in the open-chamber experiment at only ˜4° C. Simulations show that the temperature drop should reach around 10° C. if under the same weather as the sealed-chamber experiment. Also, because of the additional cooling power from radiative coolers, Sₚ rises from 1.30 W/kg/K to 1.62 W/kg/K (˜25% relative improvement). Combined, these two experiments show the most extreme cases for radiative cooling, where the N_{eff} ranges from the lowest to highest possible values for the test assembly. In most other conditions, radiative cooling provides a temperature drop between these two values.

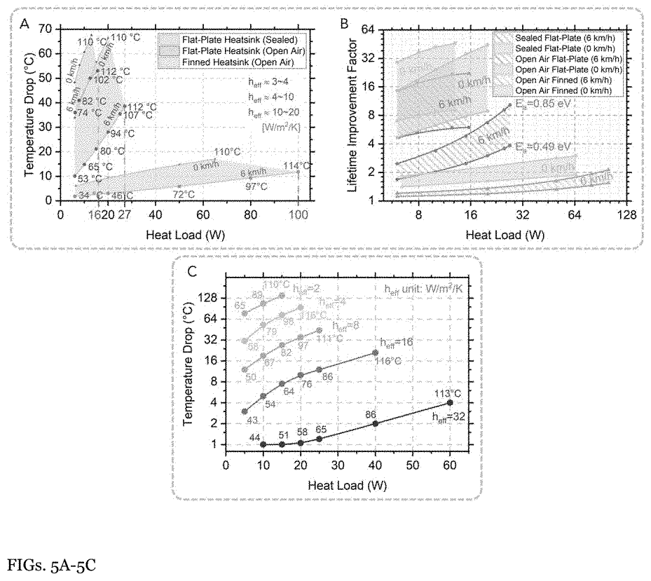

The performance of CPV radiative cooling can vary significantly with the choice of cooling design and working environment. For example, the radiative cooling power usually increases when the heat load becomes larger, as well as becoming less obvious when the convective coefficient is higher. Therefore, choice of heat sink, wind speed, and heat load all affect performance. With a better cooling design, greater heat loads can be accepted by the solar cell to improve the overall efficiency and output power. To acquire a comprehensive understanding of radiative cooling, three groups of simulations were carried out to study the performance and upper limit of multiple CPV cooling designs at 28° C. under various heat loads and wind speeds, including: a flat-plate heat sink in sealed chamber (with top LDPE film), a flat-plate heat sink in open air (without top LDPE film), and a finned heat sink in open air (without top LDPE film). The geometries of the first two groups are the same as shown in FIG. 2A, while the heat sink in the third group is replaced with a finned heat sink to achieve the greatest convective cooling power. The maximum allowed operating temperature of solar cell is assumed to be ˜110° C. The result is shown in FIG. 5A. The top and bottom lines in each of the three groups indicate working environments with wind speeds of zero (natural convection) and 6 km/h, respectively. Lower wind speeds reduce convective cooling, resulting in a higher heat sink temperature and increased radiative cooling power for a larger temperature difference. Convective cooling is very sensitive to wind speed, while radiative cooling is not directly affected by wind, making it benefit all designs and perform best in a low wind speed environment. As shown in the blue region, radiative cooling on a flat-plate heat sink in a sealed-chamber cooling structure can provide a huge temperature drop without active air cooling. However, the maximum heat load of this design is the lowest: ˜13 W (zero wind) and ˜16 W (wind speed at 6 km/h), respectively. When using a flat-plate heat sink in fully open air (top LDPE removed), radiative cooling can still provide a significant temperature drop, giving a maximum heat load of ˜20 W (zero wind) and ˜27 W (wind speed at 6 km/h). This group of simulations has a cooling structure and convective coefficient most similar to commercial CPV designs. Finally, for high-heat-load CPV systems equipped with finned heat sinks, radiative cooling can only lower the temperature by 3 to 6° C. with a 20 W heat load. However, the temperature drop can increase to 12 to 13° C. when the heat load is above 65 W, which can further increase the maximum heat load of the CPV assembly by ˜15 to 18 W compared with the non-radiative cooling design. Although the temperature drop is lower than the other two cases, the improvement to the maximum heat load from radiative cooling is the highest for the finned heat sink structure.

To summarize the radiative cooling performance under different working conditions, the temperature drop versus heat load and N_{eff} is simulated using a flat-plate geometry. FIG. 5C shows the temperature drop due to radiative cooling at different values of h_{eff}; similar to FIG. 5A, where the plot is grouped by the cooling design. As before, the corresponding temperature of Chamber 1 (with cooler) is noted by the side of each data point.

Lower operating temperatures also dramatically improve the lifetime of most solar cells, including commercially available products. In general, solar cells can be modeled to degrade over time following the Arrhenius rate equation. Depending on the material, type and fabrication quality of the PV module, the degradation rate can vary dramatically as a result of variations in the failure mechanisms and the associated activation energy Ea. Since many different types of solar cells are used in CPV systems, including III-V, multi-junction, and high-performance silicon (Si) solar cells, the following discussion will encompass these possibilities, instead of focusing on the GaSb solar cell used in the CPV test assembly. For most Si solar cells, Ea usually falls in the range from 0.7 eV to 0.9 eV. Activation energies for other materials range from 0.49 eV to 0.85 eV. Using temperature data from the experiments and simulations, the lifetime improvements by radiative cooling for each line shown in FIG. 5A are estimated in FIG. 5B. As can be seen, with different types of PV panels at an activation energy from 0.49 eV to 0.85 eV, each line from FIG. 5A expands to an area. Specifically, for the above-referenced experiment, a 4 to 13 times extension of lifetime is predicted. Similarly, roughly 0.7 to 1.5 (70% to 150%) times extension for an open-chamber structure is predicted, at a heat load and wind speed of 6 W and 6 km/h. For finned heat sink at wind speed of 6 km/h, the minimum lifetime extension from radiative cooling is 10% to 20%.

A GaSb CPV system integrating soda-lime glass-based radiative coolers is demonstrated and tested in outdoor experiments. The cooling performance is quantitatively modeled by an opto-thermal simulation, which shows a good match with experimental data. Three different cooling designs (flat-plate heat sink in sealed chamber; flat-plate heat sink in open chamber; finned heat sink in open chamber) have been investigated and quantitatively analyzed. Depending on the cooling design, heat load, and wind speed, radiative cooling performance can vary to a large extent. For flat-plate heat sinks in sealed chambers, a large temperature drop of 36° C. is achieved experimentally at a heat load of 6.1 W (DNI=1019 W/m², wind speed=6 km/h), with a 75 mV increase of V_{OC} (27% relative). A total cooling power of 310 W/m² and 170 W/m² from the top and bottom coolers, respectively, is estimated, representing 62% of the overall cooling power; furthermore, the cooling power per unit weight of the assembly disk is increased by 81%. This overall temperature reduction from radiative cooling is comparable to some active air-cooling systems, yet requires no extra power input. For this cooling design, the maximum heat load is limited to ˜16 W without active cooling. The second cooling structure uses the same flat-plate heat sink, but operates in open air to fully take advantage of natural convection. However, no active-air cooling system can be applied beyond the open-chamber structure. A temperature drop over 5° C. is achieved in outdoor tests, under a heat load of 6.4 W (DNI=1069 W/m², wind speed=20 km/h), resulting in a V_{OC} increase of 28 mV (8% relative). The radiation power from top and bottom coolers is 157 W/m² and 45 W/m², respectively, contributing to 25% of the total cooling power, which improves the specific cooling power by 25%. Three groups of simulations are conducted to further study radiative cooling performance under heat loads from 6 to 100 W, with different wind speeds and cooling designs. The results clearly show that radiative cooling benefits all cases, despite variations in heat sinks and weather conditions. While the temperature drop from radiative cooling becomes less obvious with better convective cooling, the absolute increase of maximum heat load improves (from flat-plate heat sink to finned heat sink). Lifetime extensions from the reduced operating temperatures for the corresponding designs are predicted for different types of solar cells which may be used in similar CPV systems; if confirmed, this would provide substantially improved reliability for the entire CPV system. FIGS. 5(A) and 5(C) summarize the radiative cooling performance for these designs by demonstrating the relationship between heat load, convective coefficients, and temperature drop. Finally, the radiative cooling approach presented here is not only limited to CPV, but can be applied to substantially enhance passive cooling for a wide range of applications which generate low grade heat and operate above ambient temperatures. The materials for radiative cooling are not limited to the soda-lime glass structures demonstrated in this work. Many cooling approaches, including active cooling, can be coupled with radiative coolers and provide greater cooling power, by changing the surface emissivities of the heat sink or enclosure of the device.

### EXAMPLE DETAILS

### Daytime Radiative Cooling

The detailed structure of Chamber 1 is shown in FIG. 2A. This configuration includes certain testing components such as the thermocouple and control chamber, that are not necessarily required for commercial cooling applications. The outside enclosure was made of polystyrene (PS) foam covered by Al sheets to minimize the absorption of sunlight. The enclosure protects the assembly from various weather conditions and reduces noise in the collected data. Two highly-transparent low-density polyethylene (LDPE) films were used to seal the openings on the top and the bottom of the chamber, respectively, to suppress convection and any associated temperature fluctuations caused by wind gusts. LDPE films and the foam housing are included to partially resemble the enclosed working environment seen in commercial CPV systems. Most commercial CPV systems in real application have enclosures similar to the CPV test assembly, without a large amount of direct natural convection. By placing or removing the top LDPE film, radiative cooling performance were studied under different working conditions. Additionally, although having a low thermal conductivity, the foam housing did not strongly hinder the cooling of the inside structure, since the heat convection mainly dissipates vertically through LDPE films. Simulations show that there is only a 10% relative increase of the effective convection coefficient associated with replacing the foam with a 0.05-inch-thick copper enclosure, which is comparable to a commercial CPV system. Inside the chamber, the solar cell, aluminum nitride (AlN), copper heat sink and coolers are pasted together as a cooling assembly disk at diameter of 4 inches by thermally conductive silver adhesive, to uniformly conduct heat from solar cell to coolers. The inner side of the coolers are coated with 300 nm Al as a reflection layer. Four polytetrafluoroethylene (PTFE) cubes and a PMMA ring were used to elevate the disk to limit the conductive heat transfer from the disk to the chamber walls, protecting the foam from high temperature. The electrode probes were connected to the solar cells to measure the corresponding open-circuit voltage (V_{OC}). A Type-K thermocouple was mounted next to the solar cell on the disk with silver adhesive to measure the temperature (Tₑₓₚₜ), as shown in FIG. 2B. The data was collected by a four-channel USB DAQ to record the V_{OC} and Tₑₓₚₜ.

Chamber 2 was almost an identical structure as Chamber 1, but the coolers were replaced with Al reflectors as a control. The Al was commonly used as a solar reflector to minimize solar heating of devices under direct sunlight, because of its light weight, reasonable cost, and widespread availability. Therefore, among non-radiative cooling materials, Al is one of the best choices for suppressing the temperature of outdoor systems.

Chamber 3 had the same enclosure as Chamber 1 and 2, while the inside assembly was replaced with a thermal power sensor. A meter console was connected to the sensor to measure the focused solar power. Chamber 2 and 3 are not shown here separately due to their similarities.

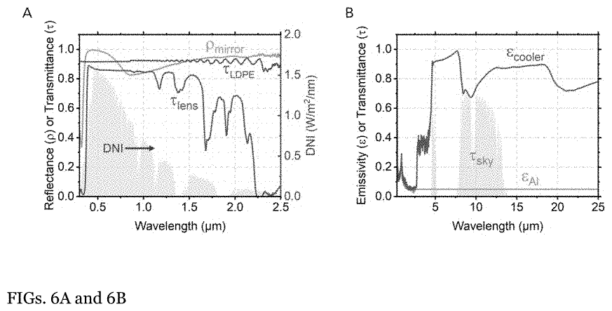

The reflectance and transmittance of the first-surface Al mirror, PMMA lens and LDPE films are shown in FIG. 6A. The high values in the solar spectrum range ensure a minimum optical loss for the CPV assembly. The spectrum direct normal irradiance (DNI) data of West Lafayette extracted from National Solar Radiation Database (NSRDB) is also shown in the same figure for reference. The emissivities of the Al reflector and cooler are shown in FIG. 6B. The transmittance of the clear sky, extracted from the MODTRAN mid-latitude summer sky model, is shown for reference. Both the Al reflector and cooler have a low emittance from 0.3 to 4 μm, minimizing the heating caused by sunlight. Above 4 μm, the high conductivity of Al gives a low mid-IR emittance, trapping heat inside the assembly disk. On the contrary, the emittance of the radiative cooler rises quickly above 5 μm, which provides a significant output cooling power in the mid-IR. All data in both figures from 0.3 to 2.5 μm is measured by spectrophotometer; data above 2.5 μm for cooler is measured on an FTIR.

### Simulation Analysis of the Experiment

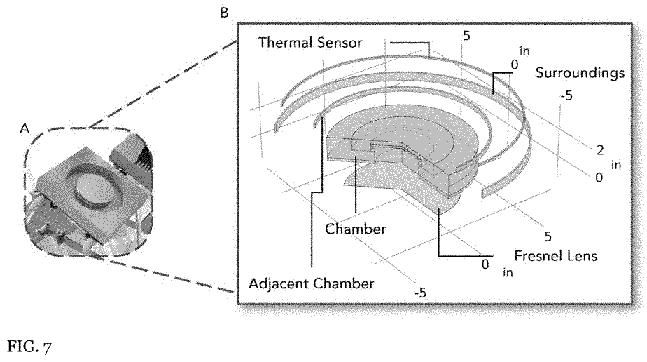

Simulations are carried out with COMSOL Multiphysics to quantitatively analyze the cooling performance and verify the experimental results. Transient heat transfer process is modeled in the software and matches well with experiment, as previously shown in FIG. 4A. To improve the efficiency, an axisymmetric structure was used as an approximation of the real structure. As seen in FIG. 7, several modifications have been made. The solar cell, the AlN, and the bottom cooler are replaced with three disks with equal surface areas and thicknesses, correspondingly, to keep the total conducted heat same. The foam wall of the chamber is adjusted to a round structure, with the same average wall thickness as in the experiment. The holder elevating the chamber is neglected, since the heat is mostly dissipated through the walls. The simplified axisymmetric geometry is verified to have a very similar performance as the original configuration in terms of heat transfer, yet it gives a much faster calculation speed. Therefore, an axisymmetric geometry is used for quantitative simulation analysis in this work.

The model includes heat transfer, laminar air flow and thermal radiation to reflect the real physics process, ensuring the reliability of the result. Material properties, including the density, thermal conductivity, heat capacity are extracted from manufacturer's data sheets and online database. The surface emissivity for each material is measured on the spectrophotometer and the FTIR spectrometer. The boundary conditions, including solar irradiance, wind speed, humidity, ambient temperature were defined based on the experimentally-measured solar power and the local weather reports, to faithfully reflect real-world experimental conditions.

Those skilled in the art will recognize that nigh-infinite modifications can be made to the specific implementations described above. The implementations should not be limited to the particular limitations described. Other implementations may be possible.

We claim:

1. A radiatively cooled solar array, comprising:
a downwardly-facing solar cell;
a mirror positioned below the solar cell and oriented to direct sunlight onto the solar cell;
a heat sink in thermal communication with the solar cell and disposed opposite the mirror;
wherein the heat sink is in radiative communication through Earth's atmosphere with outer space.

2. The radiatively cooled solar array of claim 1 and further comprising an optical concentrator positioned between the mirror and the solar cell for focusing sunlight onto the solar cell.

3. The radiatively cooled solar array of claim 3 wherein the optical concentrator is a Fresnel lens.

4. The radiatively cooled solar array of claim 1 and further comprising at least one radiative cooler operationally connected to the heat sink for radiating heat away from the solar cell.

5. The radiatively cooled solar array of claim 4 wherein the at least one radiative cooler is selected from the group consisting of soda lime glass, zinc sulfide, adhesive tape, and combinations thereof.

6. The radiatively cooled array of claim 1 wherein the mirror is adapted to track a solar source of sunlight and wherein the heat sink radiates to an outer space location spaced from the solar source of sunlight.

7. The radiatively cooled array of claim 1 and further including a scaffold operationally connected to the solar cell and mirror.

8. The radiatively cooled array of claim 1 and further comprising a thermocouple connected in thermal communication with the solar cell.

9. The radiatively cooled array of claim 8 and further comprising an electronic controller operationally connected to the thermocouple.

10. A method for radiatively cooling a solar transducer, comprising:
a) positioning a mirror to receive and reflect sunlight;
b) positioning a solar cell between the mirror and sunlight;
c) orienting the solar cell to receive reflected sunlight from the mirror;
d) positioning a radiative cooling element in thermal communication with the solar cell and opposite the mirror; and
e) radiating energy skyward from the radiative cooling element.

11. The method of claim 10 and further comprising:
f) focusing reflected sunlight onto the solar cell through a lens.

12. The method of claim 10 and further comprising:
g) automatically orienting the mirror to receive maximum sunlight.

13. The method of claim 10 wherein the solar cell is also convectively cooled.

14. A solar cell assembly, comprising:
at least one solar cell;
a support structure for supporting the at least one solar cell;
at least one mirror operationally connected to the support structure and positioned to reflect sunlight onto the at least one solar cell; and
at least one radiative cooling element operationally connected to the at least one solar cell for radiating energy skyward.

15. The solar cell assembly of claim 14 and further comprising a heat sink disposed between the solar cell and the radiative cooling element and in thermal communication therewith.
